(19) United States
(12) Patent Application Publication
(10) Pub. No.: US 2023/0317619 A1
(43) Pub. Date: Oct. 5, 2023

(54) MICROELECTRONIC STRUCTURE INCLUDING DIE BONDING FILM BETWEEN EMBEDDED DIE AND SURFACE OF SUBSTRATE CAVITY, AND METHOD OF MAKING SAME

(71) Applicant: Intel Corporation, Santa Clara, CA (US)

(72) Inventors: Ravindranath V. Mahajan, Chandler, AZ (US); Srikant Nekkanty, Chandler, AZ (US); Srinivas V. Pietambaram, Chandler, AZ (US); Veronica Strong, Hillsboro, OR (US); Xiao Lu, Chandler, AZ (US); Tarek A. Ibrahim, Mesa, AZ (US); Karumbu Nathan Meyyappan, Portland, OR (US); Dingying Xu, Chandler, AZ (US); Kristof Darmawikarta, Chandler, AZ (US)

(73) Assignee: Intel Corporation, Santa Clara, CA (US)

(21) Appl. No.: 17/711,978

(22) Filed: Apr. 1, 2022

(51) Int. Cl. H01L 23/538; H01L 21/48

(52) U.S. Cl. CPC H01L 23/5381; H01L 21/486; H01L 23/5384

(57) ABSTRACT

A microelectronic structure, a semiconductor package including the same, and a method of forming same. The microelectronic structures includes: a substrate defining a cavity therein; a bridge die within the cavity, the bridge die to electrically couple a pair of dies to be provided on a surface of the substrate; an electrical coupling layer between a top surface of the cavity and a bottom surface of the bridge die. The electrical coupling layer includes: a non-conductive component including a die bonding film and defining holes therein; and electrically conductive structures in the holes, the electrically conductive structures electrically coupling the substrate with the bridge die.

### TECHNICAL FIELD

This disclosure relates generally to microelectronic assemblies including a substrate and a die embedded therein.

### BACKGROUND

Microelectronic assemblies of the state of art that include a bridge die embedded in a substrate (i.e. a die embedded in a substrate and providing a signal coupling between two or more dies supported by the substrate) involve the provision of an embedded bridge die that includes horizontal electrically conductive interconnects therein which provide the noted signal coupling function. The bridge die may, for example, correspond to an embedded multi-die interconnect bridge (EMIB). The interconnects are “horizontal” in that they run for the most part along a length direction of the bridge die. As microelectronic assemblies scale, improved structures are needed that allow the attendant scaling of the density of electrical connections between the bridge die and the two or more dies that it couples electrically.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 is a cross sectional view of a microelectronic assembly including an embedded die bridge based on the state of the art.

FIGS. 2 and 3 are views similar to that of FIG. 1 showing a microelectronic structure according to a first embodiment.

FIGS. 4A-4E represent cross-sectional views of successive temporary microelectronic assemblies in a flow to create a microelectronic structure similar to that of FIG. 2.

FIGS. 5A-5D represent cross-sectional views of successive temporary microelectronic assemblies in a flow to create the microelectronic structure of FIG. 2.

FIGS. 6A-6E represent cross-sectional views of successive temporary microelectronic assemblies in a flow to create a microelectronic structure according to a first example of a second embodiment.

FIGS. 7A-7D represent cross-sectional views of successive temporary microelectronic assemblies in a flow to create a microelectronic structure according to a second example of the second embodiment.

FIG. 8 is a cross-sectional side view of an integrated circuit device assembly that may include a microelectronic structure in accordance with any of the embodiments disclosed herein.

FIG. 9 is a block diagram of an example electrical device that may include a MCP assembly, in accordance with any of the embodiments disclosed herein.

FIG. 10 is a flow chart of a process according to some embodiments.

### DETAILED DESCRIPTION

Some embodiments provide a microelectronic structure including: a substrate defining a cavity therein; a bridge die within the cavity, the bridge die to electrically couple a pair of dies to be provided on a surface of the substrate; an electrical coupling layer between a top surface of the cavity and a bottom surface of the bridge die. The electrical coupling layer includes: a non-conductive component including a die bonding film and defining holes therein; and electrically conductive structures in the holes, the electrically conductive structures electrically coupling the substrate with the bridge die.

Advantageously, a microelectronic assembly according to embodiments provides an effective sealant layer encapsulating the electrical structures (joints) coupling the bridge die to the substrate into which the bridge die is embedded. Embodiments obviate issues caused by having to provide solder joints followed

By “electrically conductive structure,” what is meant herein is any electrically conductive body used in a microelectronic structure, such as conductive contacts, pads, traces, lines, interconnects, vias, or other features by way of example. An “electrically conductive structure” as used herein may include an electrically conductive structure that is to provide direct or indirect electrical coupling between two microelectronic components.

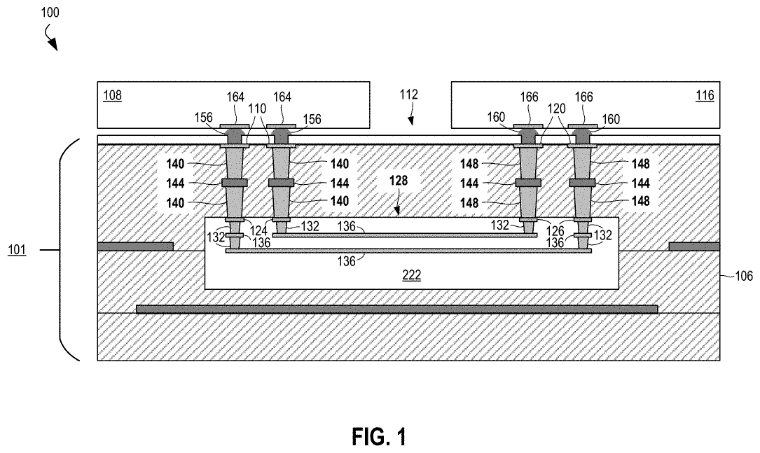

In FIGS. 1-7D, some reference numerals may be referred to in the alternative, such as, by way of example, referring to an element “Xa/Xb.” In such a case, reference is being made to each of element Xa and element Xb, individually, and the notation Xa/Xb would have been used for the matter of conciseness.

An explanation will now follow below regarding the state-of-the-art in the context of FIG. 1.

FIG. 1 is a cross-sectional view of an example microelectronic assembly 100 including a bridge die 122 embedded within a substrate 104, and two dies 108 and 116 supported on a top surface 112 of the substrate 104. In FIG. 1, the combination of the substrate 104 and bridge die 122 will together be referred to as a microelectronic structure 101. Substrate 104 may include a core layer including sublayers of a non-conductive material, such as glass, silicon or an organic material, and conductive traces 144 extending through the sublayers to conduct electrical signals therethrough. A first integrated circuit die 108 is attached to a top surface 112 of the substrate 104 via electrically coupling components or joints 156 connecting to die conductive contacts 164 and substrate conductive contacts 110. A second integrated circuit die 116 is attached to the face 112 via coupling components 160 connecting to die conductive contacts 166 and substrate conductive contacts 120.

Bridge conductive contacts 124 and 126 are located on a face 128 of the bridge 100. Bridge vias 132 and bridge conductive traces 136 provide conductive pathways between the conductive contacts 124 and 126. Substrate vias 140 and substrate conductive traces 144 provide conductive pathways from the substrate conductive contacts 110 to the bridge conductive contacts 124 and substrate vias 148 and substrate conductive traces 144 provide conductive pathways from the substrate conductive contacts 120 to the bridge conductive contacts 126. Together, conductive contacts 110, 120, 124, 126, vias 132, 140, 148, and conductive traces, 136, 144 provide conductive pathways between integrated circuit dies 108 and 116 and thus allow them to be communicatively coupled.

Although the embedded bridge die 122 is shown as being fully embedded within the substrate component 104, in some embodiments, it can be partially embedded, with the bridge face 128 being part of the face 112 of the first substrate component 104. In such embodiments, the bridge conductive contacts 124 and 126 can be located at the face 112 of the substrate component 104 and the integrated circuit dies 108 and 112 can connect to the bridge conductive contacts 124 and 126 via coupling components 156 and 160, respectively.

Improvements are needed providing conductive pathways within a microelectronic structure that includes a bridge die, such improvements to allow the provision of subassemblies with improved electrical pathway density as devices scale, while continuing to provide robust bridge die to substrate electrical connections.

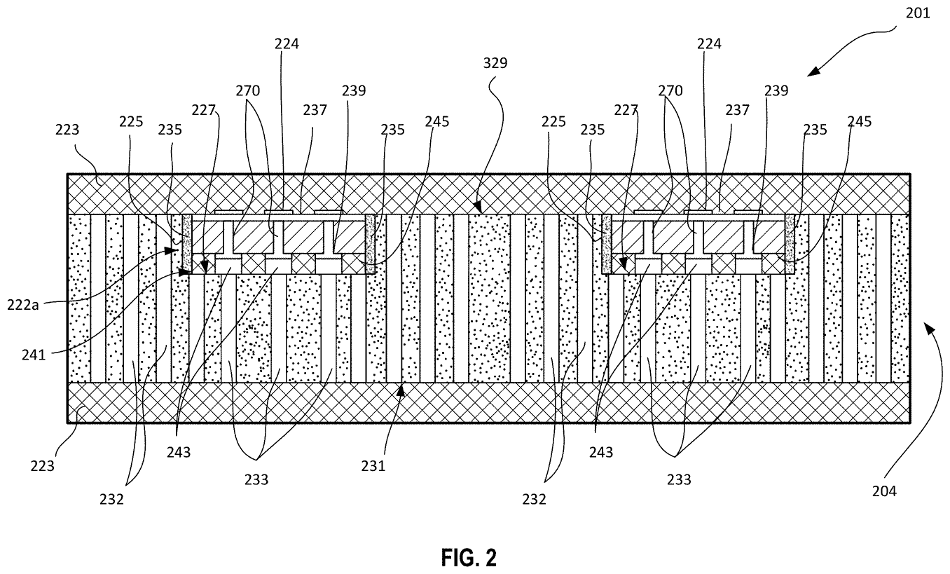

Details of some embodiments will be described in further detail in relation to FIGS. 2-7D below, after general remarks, in the immediate next few paragraphs, regarding the scope of the disclosure.

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims. In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials, and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the instant detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized, and structural or logical changes may be made without departing from the scope of the present disclosure. Therefore, the following detailed description is not to be taken in a limiting sense, and the scope of embodiments is defined by the appended claims and their equivalents.

The technologies described herein may be implemented in one or more electronic devices. Non-limiting examples of electronic devices that may utilize the technologies described herein include any kind of mobile device and/or stationary device, such as microelectromechanical systems (MEMS) based electrical systems, gyroscopes, advanced driving assistance systems (ADAS), 5G communication systems, cameras, cell phones, computer terminals, desktop computers, electronic readers, facsimile machines, kiosks, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. Such devices may be portable or stationary. In some embodiments, the technologies described herein may be employed in a desktop computer, laptop computer, smart phone, tablet computer, netbook computer, notebook computer, personal digital assistant, server, combinations thereof, and the like. More generally, the technologies described herein may be employed in any of a variety of electronic devices, including semiconductor packages with passive heat spreaders, interface layers, TIMs, top dies, side dies, substrates, and package substrates.

As used herein the terms “top,” “bottom,” “upper,” “lower,” “lowermost,” and “uppermost” when used in relationship to one or more elements are intended to convey a relative rather than absolute physical configuration. Thus, an element described as an “uppermost element” or a “top element” in a device may instead form the “lowermost element” or “bottom element” in the device when the device is inverted. Similarly, an element described as the “lowermost element” or “bottom element” in the device may instead form the “uppermost element” or “top element” in the device when the device is inverted.

Reference will now be made to FIGS. 2-7D, which show various stages in the formation of a microelectronic assembly according to various embodiments.

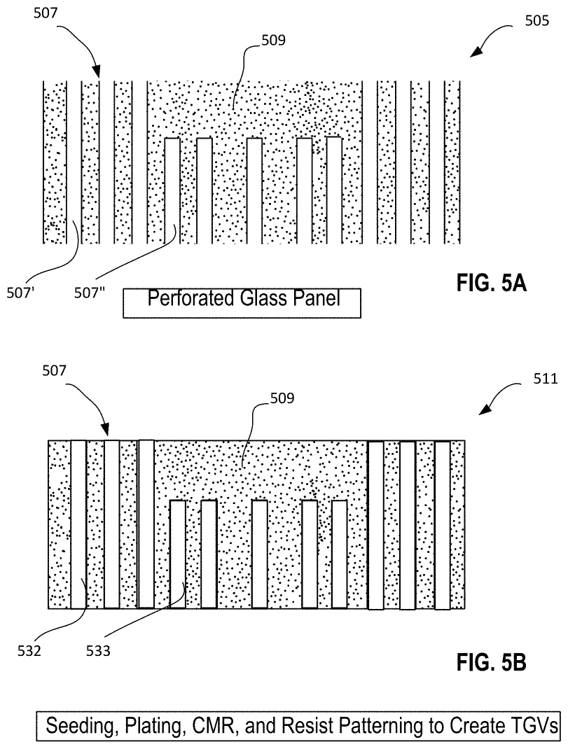

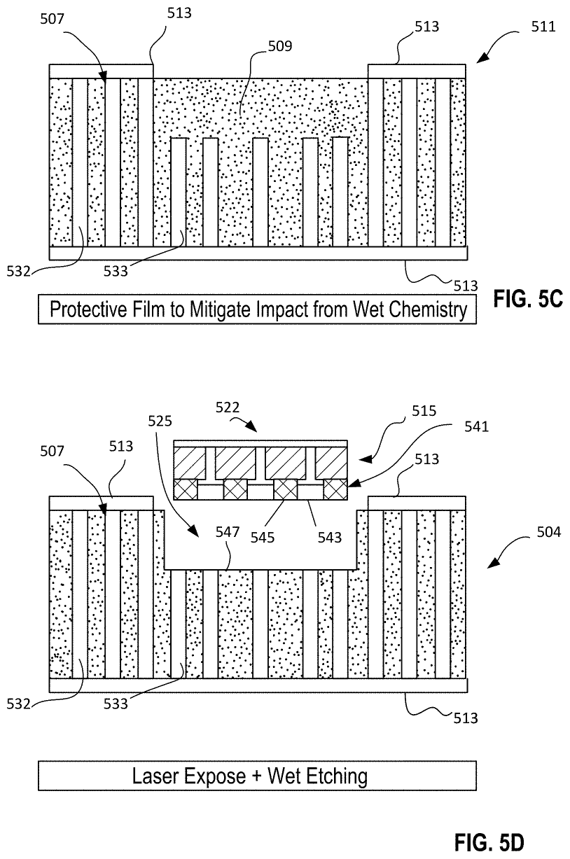

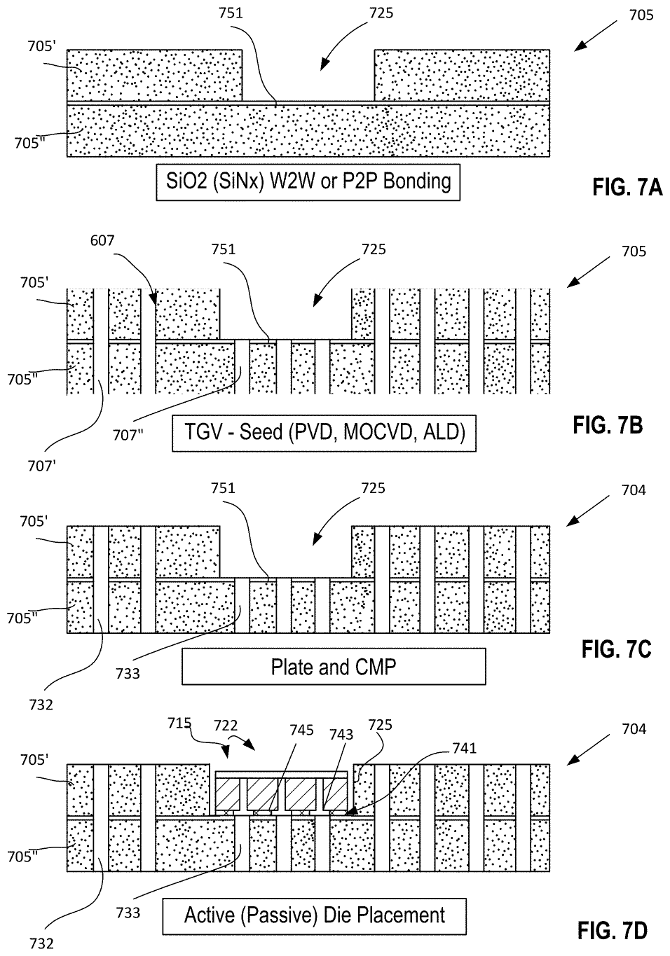

As between FIGS. 2-7D, like components are indicated using like reference numerals, and, therefore, a description of such components may not be provided again in the context of the figures as the description progresses. For instance, if we have a component “222” described in the context of FIG. 2, the component “222” is meant to correspond to a component “522” described in FIG. 5 and to a component “722” in FIG. 7, and, unless the respective figures depictions and/or the respective descriptions of components “222,” “522” and “722” differ from one another, a description given herein with respect to any of the noted components “222,” “522” and “722” with like reference numerals is means to apply to the remaining ones of the components “222,” “522” and “722.”

In addition, as between FIGS. 2-7D, where a same component depicted in the same way as between two figures is described in detail in one figure with respect to its various features, manner of fabrication, functionalities and/or advantages, it is to be understood that, unless otherwise stated, the very same component shown in another figure is similar to the one already described with respect to its various features, manner of fabrication, functionalities and/or advantages, and, as such, a description of that same component may not be repeated across figures.

In FIGS. 2-7D, in instances where single layers may have been depicted in FIGS. 2-7D, it is to be appreciated that such layers may be made of multiple sublayers having the same or different material compositions.

In the shown embodiments of FIGS. 2-7D, the substrate may include a core substrate or an interposer substrate. The substrate may comprise a glass, organic and/or silicon material. In examples including a core substrate, the substrate may include a generally central core. In many examples, such core may include a resin-filled glass fiber structure, which in some examples may be clad on opposing sides with a copper (Cu) or other metal which extends in a pattern forming conductive traces. In many examples, the substrate may include additional buildup layers, that is layers of conductors separated by dielectric to each side of the core, such as, for example an epoxy-based laminate material, such as, for example, Ajinomoto Build-up Film (ABF), or other materials known to persons skilled in the art. A substrate according to some embodiments may further include a coreless base substrate, one formed of multiple laminate layers, has with the cored substrates. One example of such a coreless substrate is a substrate manufactured through a bumpless build up layer (BBUL) process, in which micro-vias form interconnections between conductive structures in the buildup layers and external contact surfaces. In other examples, the substrate can include glass, ceramic, and/or semiconductor materials; and may include multiple laminations of copper or another conductor in addition to such dielectric materials.

According to another embodiment, the substrate may further include a printed circuit board (PCB), and/or a motherboard. The PCB may be made of an FR-4 glass epoxy base with thin copper foil laminated on both sides. For some embodiments, a multilayer PCB can be used, with pre-preg and copper foil used to make additional layers. For example, the multilayer PCB may include one or more dielectric layers, where each dielectric layer may be a photosensitive dielectric layer. The PCB may include a plurality of conductive layers, which may further include copper (or metallic) traces, lines, pads, vias, via pads, holes, and/or planes.

In the shown embodiments of FIGS. 2-7D, although a substrate is shown including through silicon vias extending therethrough, it is to be understood that embodiments are not so limited, and include within their scope a substrate which includes vias extending therethrough, whether through vias or blind vias, and conductive traces extending therethrough in a direction generally transverse to that of the vias.

In the shown embodiments of FIGS. 2-7D, although the bridge dies are shown as including only through vias therein as electrically conductive pathways therein, the bridge dies may further include horizontally running electrically conductive traces (not shown) extending transverse to the through vias to allow an electrical coupling or bridging of two or more surface dies supported by the substrate 204 (such as dies on the top buildup layer 223) to each other.

In the shown embodiments of FIGS. 2-7D, any vias, traces, contact pads or other electrically conductive components of either the substrate or the bridge die will be referred to as “electrically conductive features.”

In the shown embodiments of FIGS. 2-7D, a bridge die may include an active die or a passive die, and one microelectronic structure may include both an active bridge die and a passive bridge die embedded therein. A “passive” component as used herein provides only conductive pathways or interconnections/electrical coupling between two or more die secured on a top surface of the substrate.

Dies thus connected to each other via bridge dies are referred to herein as “surface dies.”

An “active die” is a die with active circuit components such as relatively simple circuits (such as, for example, filters, voltage limiters, and the like), to much more complex circuits including, for example transistors, fuses or anti-fuses, and/or other programmable elements (such as programmable logic devices (PLMs), field programmable logic arrays (FPGAs), etc.

In the embodiments of FIGS. 2-7D, although not shown, each of the buildup layers may include a plurality of sublayers comprising a dielectric material, electrically conductive traces therebetween, vias extending therethrough (either partially or totally).

The microelectronic subassemblies resulting from and/or shown in FIGS. 2-7D may be combined with a plurality of surface dies supported by the substrate (for example supported on a top surface of the substate as suggested in the example of FIG. 1), where bridge dies of the microelectronic subassemblies electrically couple the plurality of dies to each other.

In the embodiments of FIGS. 2-7D, any of the bridge dies may be embedded into a cavity of the substrate either with its backend facing the cavity, or with its backend facing away from the cavity.

In the embodiments of FIGS. 2-7D, although the bridge dies are shown as having been electrically coupled to the substrate's through vias (as shown, blind through vias), embodiments are not so limited, and encompass within their scope an electrical coupling of a bridge die to any electrically conductive components of the substrate, whether a via, a trace, an interconnect layer, etc.

In the instant description, “non-conductive” means “electrically insulating” or “electrically non-conductive” or “not electrically conductive.” For context, as used herein, “electrically conductive” or “conductive” refers to a property of a material having an electrical conductivity greater than or equal to 10⁷ Siemens per meter (S/m) at 20 degrees Celsius. Examples of such materials include Cu, Ag, Al, Au, W, Zn and Ni.

In the shown embodiments of FIGS. 2-7D, although the cavity is shown as having been provided in a single layer of substrate material, embodiments encompass the provision of a cavity that extends through any number of substrate sublayers.

In the shown embodiments of FIGS. 2-7D, whenever a description is provided as to a bridge die being provided inside a cavity of a substrate it is to be understand that such provision may include a bonding of the bridge die to a cavity surface, for example by using an adhesive.

In the shown embodiments of FIGS. 2-7D, electrical connections to a bridge die provided through a top surface of the cavity in which the bridge die is embedded may allow, by way of example, the ability to power the bridge die through the substrate.

Reference is now made to FIG. 2, which shows a microelectronic structure 201 including a substrate 204 and a plurality of bridge dies 222a and 222b embedded therein. The bridge dies 222a and 222b are shown as having been embedded into cavities 225 such that their backsides face the top surface 227 of their respective cavities 225 as shown. The microelectronic structure 201 further includes buildup layers 223 on a top surface 229 and on a bottom surface 231 thereof as shown.

The substrate 204 defines through vias 232 extending therethrough between top surface 229 and bottom surface 231 thereof. Substrate 204 further defines bridge die vias 233, which provide electrical coupling from buildup layer 223 to the bridge dies 222. For example, bridge die vias 233 may include an electrically conductive material therein, such as, for example, Cu, to provide electrically conductive pathways across the substrate 204 between buildup layer 223, and between bottom buildup layer 223 and the bridge dies 222a and 222b.

Bridge dies 222a and 222b are encapsulated at sides thereof by an encapsulating or mold structure 235, such as one including an underfill material, including a polymer or polymer resin. The mold structure may, for example, include Ajinomoto Build-Up Film (ABF).

Bridge dies 222a and 222b may include active components 237 therein, although embodiments, as noted previously, encompass bridge dies that are passive as well. Bridge dies 222a and 222b further include through vias 270 extending therein, along with electrical contact pads 224 electrically coupling the bridge dies 222a and 222b to the top buildup layers 223 as shown. At bottom surfaces thereof, the bridge dies 222a and 222b include electrical contact pads 239, which help to couple the bridge dies 222a and 222b to the underlying bridge die vias 233 extending through the substrate 204.

In the embodiment of FIG. 2, between the top cavity surface 227 and the bridge die 222a/222b, there exists an electrical coupling layer 241, which includes electrically conductive structures 243 in registration with respective ones of the bridge die vias 233 of the substrate 204. The electrical coupling layer 241 further includes a non-conductive component 245 within which the electrically conductive structures 243 are embedded. The electrically conductive structures 243 register with contact pads 239 of the bridge dies 222a and 222b.

The non-conductive component 245 may provide a seal function and structural integrity to the electrically conductive structures 243, similar to benefits provided for example to solder joints by an underfill material. The no-conductive component may include a patch, film or socket layer, for example a die bonding film with perforations/openings/holes therein to accept respective ones of the electrically conductive structures 243. The die bonding film may include a tape material, such as dicing tape or a non-conductive die attach film.

The non-conductive component 245 may, according to an embodiment, include a polymer material. For example, the non-conductive component 245 may include at least one of a thermoplastic or a thermosetting polymer resin. The non-conductive component may, in addition, be incorporated with a non-conductive filler. The composite of the thermoplastic or thermosetting polymer and the filler may for example be coated on a liner, and laminated on a carrier (for support) using pressure and heat.

The non-conductive component 245 may include an organic resin such as an epoxy material, polyimides, bismaleimides, acrylates, silicone, cyanate esters.

Non-conductive fillers of the non-conductive component 245 may include one or more of silica, alumina, aluminum hydroxide, mica, glass, and organic fillers such as PET (polyethylene terephthalate). For example, non-conductive fillers may include polyolefin such as a low-density polyethylene, straight chain polyethylene, intermediate-density polyethylene, high-density polyethylene, very low-density polyethylene, random copolymer polypropylene, block copolymer polypropylene, homopolypropylene, polybutene, polymethylpentene, ethylene-vinylacetate copolymer, ionomer resin, ethylene(meth)acrylic acid copolymer, ethylene(meth)acrylic acid ester (random or alternating) copolymer, ethylene-butene copolymer, ethylene-hexene copolymer, polyurethane, polyester such as polyethyleneterephthalate and polyethylenenaphthalate, polycarbonate, polyetheretherketone, polyimide, polyetherimide, polyamide, whole aromatic polyamides, polyphenylsulfide, a fluorine resin, polyvinyl chloride, polyvinylidene chloride, a cellulose resin, a silicone resin.

The liner of the non-conductive component 245 may include a polymer.

The electrically conductive structures 243 may include, according to an embodiment, liquid metal interconnects contained within through holes of the non-conductive components 245. The liquid metal may be provided, for example, by way of a liquid metal printing process.

Liquid metal interconnects used for the electrically conductive structures 243 may include any liquid metal that is liquid at room temperature, and/or at normal operating temperatures of a microelectronic assembly. In some embodiments, the liquid metal comprises gallium or an alloy of gallium, such as, for example, alloys of gallium and indium, eutectic alloys of gallium, indium, and tin, and eutectic alloys of gallium, indium, and zinc.

Optionally, the electrically conductive structures 243 include solder interconnects, where the solder is conformal with perforations within the non-conductive structure/die bonding film 245. The solder may have been provided in the form of microballs of solder inside holes of the non-conductive structure, and the resulting structure then subjected to a reflow process in order to flow the solder to conform to the shape of the hole outlines of holes within the non-conductive structure.

Advantageously, the liquid metals used herein may be flexible and stretchable. As such, they can accommodate manufacturing variations, which can lead to yield improvements and improved mechanical robustness. For example, liquid metal electrically conductive structures 243 can accommodate flex or warpage in a packaged integrated circuit component or differences in flex or warpage between microelectronic assembly components.

Advantageously, the provision of liquid metal as the electrically conductive structures 243 allows the provision of electrically conductive structures without the necessity to perform an annealing or reflow process, as would be the case with the use of solder for example.

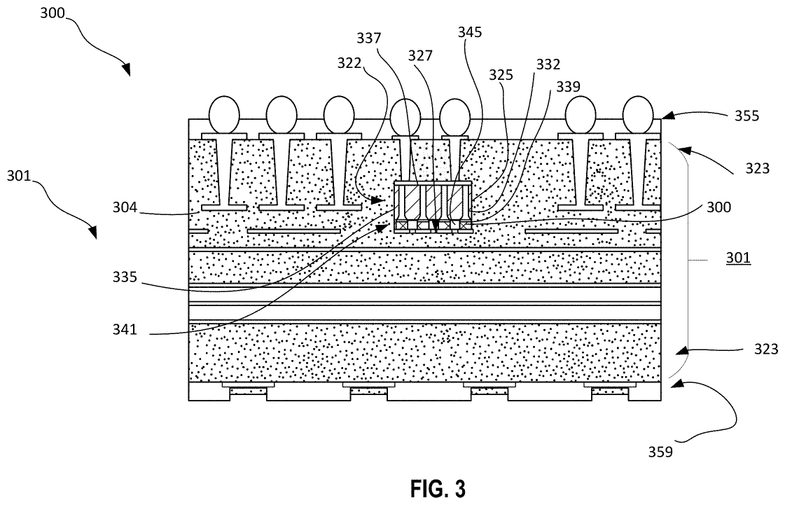

FIG. 3 is a microelectronic assembly 300 including a microelectronic structure 301 comparable to the microelectronic structure 201 of FIG. 2 described above. Thus, like components in FIG. 3 to those of FIG. 2 marked with like reference numerals will not be described again in detail here as they would correspond to similar components in FIG. 2. Some notable differences between the microelectronic structure 301 of FIG. 3 and that of FIG. 2 is that, in FIG. 3, the substrate does not include show through vias, there is a single bridge die shown instead of two, and the bridge die in FIG. 3 is connected to conductive traces at a backside thereof.

Therefore, FIG. 3 shows a microelectronic structure 301 including a substrate 304 and a bridge die 322 embedded therein. The bridge die 322 is shown as having been embedded into cavity 325 such that its backside faces the top surface 327 of its cavity 325. The microelectronic structure 301 further includes buildup layers 323 on a top surface and on a bottom surface thereof as shown.

Substrate 304 further defines bridge die vias 351, which provide electrical coupling from top buildup layer 323 to the bridge die 322.

Bridge die 322 are encapsulated at sides thereof by an encapsulating or mold structure 335.

Bridge die 322 may include active components 337 therein, although embodiments, as noted previously, encompass bridge dies that are passive as well. Bridge die 322 further includes through vias 332 extending therein, along with electrical contacts pads (not shown) electrically coupling the bridge die 322 to the top buildup layers 323 as shown. At a bottom surface thereof, the bridge die 322 includes electrical contacts 339, which help to couple the bridge die 322 to the underlying traces extending through the substrate 304.

In the embodiment of FIG. 3, between the top cavity surface 327 and the bridge die 322, there exists an electrical coupling layer 341, which includes electrically conductive structures 343 in registration with respective traces of the substrate 304. The electrical coupling layer 341 further includes a non-conductive component 345 within which the electrically conductive structures 343 are embedded. The electrically conductive structures 343 register with contact pads 339 of the bridge dies 322a and 322b.

A solder ball layer 355 is provided above the top buildup layer 343 to allow the bonding of surface dies to the microelectronic structure, similar to surface dies 108 and 116 of FIG. 1. A contact pad layer 359 is provided at a bottom surface of the bottom buildup layer to allow electrical connections to another microelectronic component, such as, for example, a motherboard.

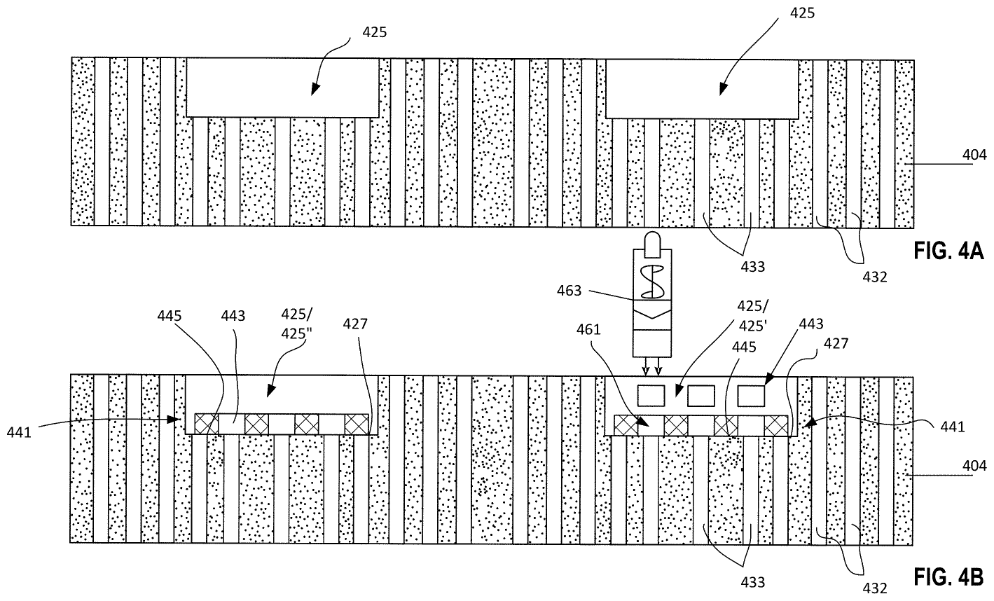

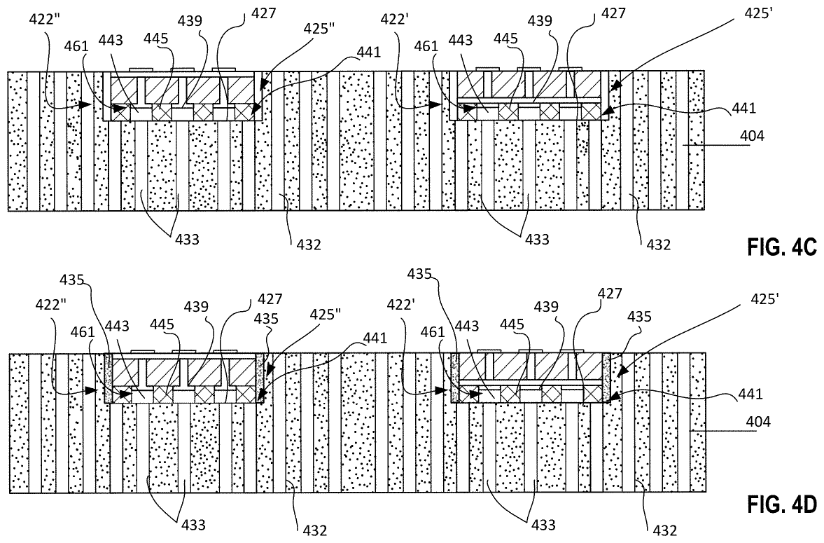

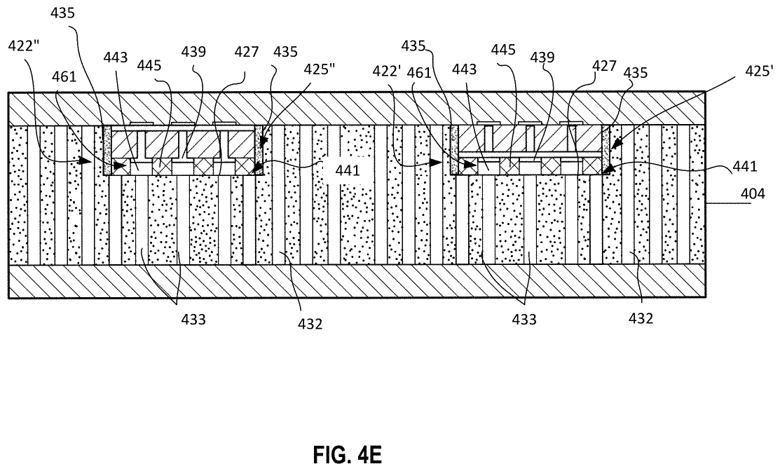

Reference is now made to FIGS. 4A-4E, a flow is provided for operations to arrive at a microelectronic structure as shown in FIG. 4E, which is comparable to that of FIG. 2 as explained above.

At FIGS. 4A, a glass substrate 404 is provided including through vias 433 therein. At this stage, cavities 425 are created in the substrate 404 including the pre-existing through vias 432, for example using a laser ablation process, or a laser ablation process along with etching. A depth to length ratio of about 2 is possible for the cavities 425 for a 500 μm thick glass core substrate 404, for example yielding a cavity having a depth of about 100 μms and a length of about 200 μms. Such a depth to length ratio provides the opportunity for different embedded stack options.

Referring next to FIG. 4B, an electrical coupling layer 441 may be provided on the top surface 427 of cavity 425, according to a first option by first providing the non-conductive component, and then providing the electrically conductive structures in holes thereof, or, to a second option, by providing the electrical coupling layer 441 as a whole including both the non-conductive component 445 and electrically conductive structures.

The electrical coupling layer 441 is provided such that the electrically conductive structures 443 thereof are in registration with corresponding bridge die vias 433 of the substrate 404 as shown.

Optionally, an additional adhesive layer (now shown) may be provided onto the cavity 425 prior to placing the non-conductive component 445 therein in order to help the non-conductive component 445 adhere to the stop surface of cavity 425.

There are multiple ways of providing the electrical coupling layer 441 onto the cavity top surface 425 as will be explained below.

According to the first option, the non-conductive component 445 may be provided onto the cavity top surface first, and then the electrically conductive structures 443 provided therein. This option is shown in the cavity 425′ of FIG. 4B. In this option, the non-conductive component 445, in the form of a die bonding film, may be provided in the cavity for example with holes 461 already formed therein, in which case a pick-and-place procedure may be use to place the non-conductive component in the cavity. Alternatively, the non-conductive component 445 may be placed therein initially without holes, for example using a pick-and-place procedure. Thereafter, holes 461 may be provided therein through patterning. The patterning may be provided for example using a semi-additive (SAP) process using lithography.

According to this first option as shown in the context of cavity 425′ of FIG. 4B, the electrically conductive structures may then be formed within the holes 461 of the non-conductive component 445. If the electrically conductive structures are made of liquid metal, the liquid metal may be dispensed using a liquid metal dispenser 463, and for example be printed onto the holes 461 of the non-conductive component 445. For example, a ball attach tool may be used to dispense the liquid metal into their respective holes 461.

According to an alternative option for this first option, instead of liquid metal, micro-balls including solder may be placed inside the holes 461 once the non-conductive component is placed within the cavity. Such micro-balls may for example be between about 50 to about 75 μms at a pitch of about 90 to about 130 μms. Solder joints with a 75 μm pitch starting from a micro ball size of 40 μms are possible. A pitch of 40 μms should be possible according to this second option as well.

According to the second option for providing the electrical coupling layer 441, as noted previously, the electrical coupling layer 441 may be provided in the cavity as a whole including both the non-conductive component 445 and electrically conductive structures 443, as shown with respect to cavity 425″ in FIG. 4B. In such a case, the electrical coupling layer 441 may be a preformed layer with electrically conductive structures 443 already provided in the holes 461 of the non-conductive component 445 when the electrical coupling layer 441 is placed in the cavity 425″.

Advantageously the liquid metal or reflowed solder will conform to the morphology of the sides walls of holes 461, and allow the non-conductive component to provide 345 to provide a seal and to impart structural robustness to the electrically conductive structures 443 through temperature cycling of the substrate 404. In this manner, the need to use underfill after formation of electrical joints between the bridge dies and the substrate, which, as devices scale, is difficult to provide in a way that does not result in holes/voids in the area of the joints, is obviated, and replaced with a robust seal around the joints provided by the electrically conductive structures that further imparts structural stability.

Where the electrically conductive structures include liquid metal that is gallium-based, there is a possibility that it may corrode the electrically conductive materials, such as the copper or other materials, of the bridge die vias 433, or of the contact pads 439 of the bridge dies 422 (FIG. 4C). Therefore, according to one option, caps may be provided onto the liquid metal, such as caps (discrete layers) including nickel or tungsten between the liquid metal and on the one hand, the bridge die vias 433, and on the other hand, the contact pads 439 of the bridge dies 422.

Referring now to FIG. 4C, bridge dies 422′ and 422″ may be provided in the cavities 425′ and 425″ respectively such that they rest on the electrical coupling layers 441, and such that conductive pads 439 of bridge dies 422′ and 422″ are in registration with corresponding ones of the electrically conductive structures 443. In the shown embodiment, the contact pads 432 of bridge dies 422′ and 422″ may fit within the holes of the non-conductive component 441 as shown. Bridge die 422′ is provided such that its backside faces the top surface 427 of its cavity 425′. Bridge die 422″ is provided such that its front end faces the top surface 427 of its cavity 425″, and this, either option is feasible according to embodiments.

Referring now to FIG. 4D, an encapsulating structure 435 is provided to encapsulate the bridge dies and to fill spaces between the bridge dies and walls/boundaries of their respective cavities 425′ and 425″. The encapsulating structure may, for example, include an epoxy molding compound or any other resin material which may be cured to provide physical encapsulating of the bridge dies in the cavities.

Referring next to FIG. 4E, buildup layers 423 may be provided on a top surface 429 and on a bottom surface 431 of substrate 404 in a manner as would be within the knowledge of a skilled person.

Reference is now made to FIGS. 5A-5D, which show a flow for providing the substrate 504 (comparable to substrate 404 of FIG. 4A) with through vias 532 therein prior to the provision of a cavity 525 therein for the embedding of a bridge die 522.

Referring first to FIG. 5A, a perforated glass panel 505 is provided. Glass panel 505 is to become a substrate 504 after further processing. The perforations or open trenches 507 in glass panel 505 may be provided by way of laser drilling or a laser etch process. Trenches 507 include open trenches 507′ to be filled with a conductive material to create through vias 532, and blind trenches 507″ to be filled with a conductive material to create bridge die vias 533. The glass panel of FIG. 5A includes a cavity block region 509 that is to be removed to define cavity 525 in its place.

Referring now to FIG. 5B, the trenches may be filled with a conductive material, for example by seeding (e.g. with TiCu), plating (e.g. with Cu), chemical mechanical polishing (CMP) and/or resist patterning to create the through vias 532 and bridge die vias 533, and to provide a glass and via panel 511.

Referring now to FIG. 5C, a protective film 513 may be provided on the top and bottom surfaces of the glass and via panel 511. The film may include a polyethylene terephthalate material, or may include a dry film resist material. The film 513 is provided to protect the vias from a wet etch chemistry to be applied in a process to provide cavity 525, as will be explained in the context of FIG. 5D below.

Referring now to FIG. 5D, the cavity 525 may be created using for example a laser material removal process followed by a wet etch. Thereafter, the film 513 may be removed, in which case we would have a substrate 504 comparable to substrate 404 of FIG. 4A, except that substrate 504 shows one cavity instead of two.

Referring still to FIG. 5D, in the shown embodiment, a bridge die assembly 515 is provided within cavity 525. The bridge die assembly 515 includes a bridge die 522, and electrical coupling layer 541. Electrical coupling layer thus includes non-conductive component 545 defining holes therein, and electrically conductive structures 543 in the holes. In the embodiment of FIG. 5D, instead of providing the electrical coupling layer inside the cavity first, and thereafter providing the bridge die thereon, an assembly 515 may be provided which includes the combination of a bridge die and its electrical coupling layer, which assembly is then positioned in its corresponding cavity.

The electrical coupling layer 541 may be provided on the bridge die 522 in the same manners described above in relation to the provision of the electrical coupling layer 441 on the top surface 547 of cavity 525. Thus, an electrical coupling layer 541 may be provided on the cavity side surface of bridge die 522, according to a first option by first providing the non-conductive component on that surface, and then providing the electrically conductive structures in holes thereof, or, to a second option, by providing the electrical coupling layer 541 as a whole including both the non-conductive component 545 and electrically conductive structures 543 on the noted surface of bridge die 522, in the same manners as noted above with respect to the first and second options described in the context of FIGS. 4A-4E, including the provision of an encapsulating/mold structure in open spaces within the cavity, and, optionally, a polishing operation before the provision of buildup.

It is noted that resist film 513 may be removed before or after bridge die assembly 515 placement into cavity 525. After placement of the bridge die assembly 515 into the cavity and removal of film 513, operations similar to those noted in FIGS. 4D and 4E may be performed in order to arrive at a microelectronic structure comparable to the one shown in FIG. 4E, including the a polishing operation after provision of an encapsulating structure inside cavity spaces, and the provision of buildup layers on top and bottom surfaces of the substrate.

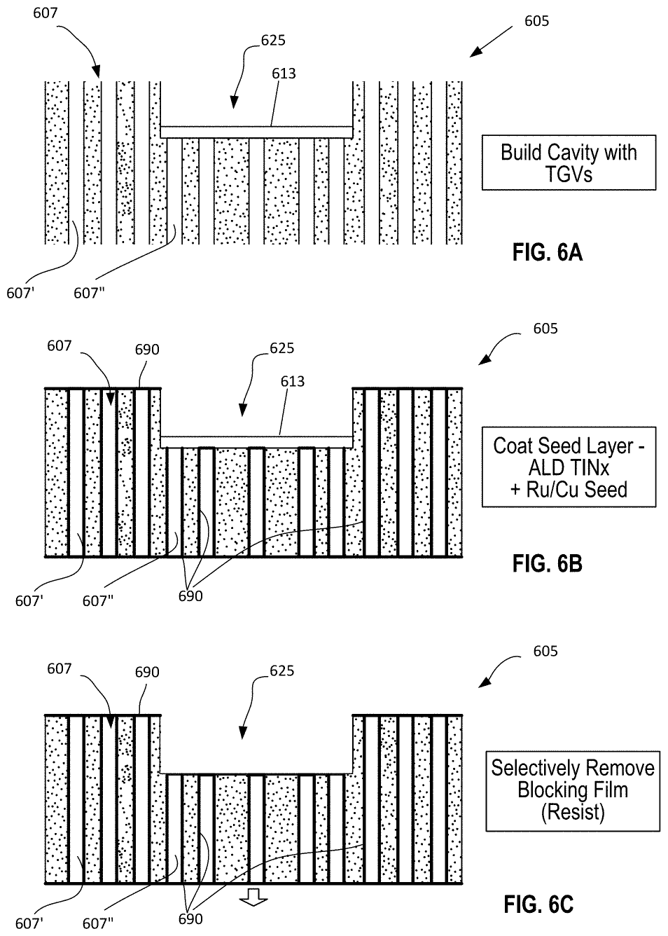

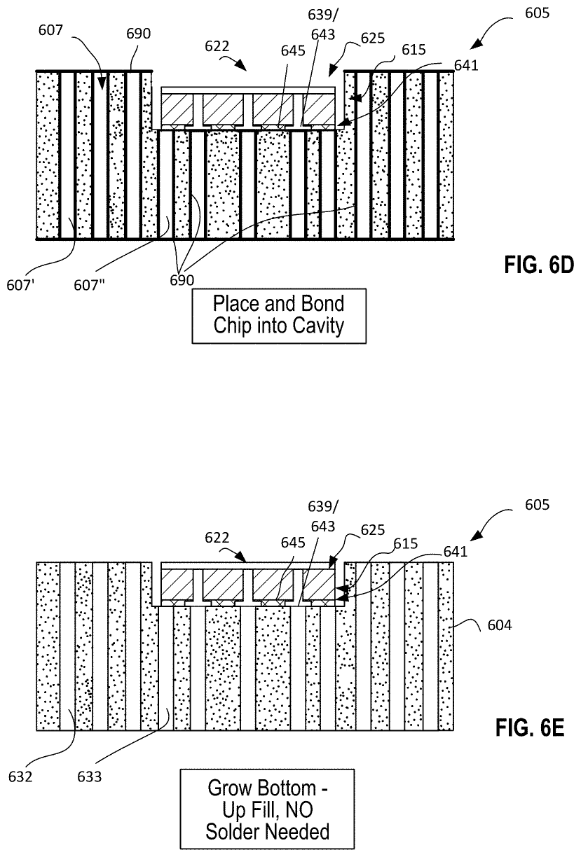

Reference is now made to FIGS. 6A-6E, which show a flow for providing the substrate 604 (comparable to substrate 404 of FIG. 4A) with through vias 632 therein after the provision of a bridge die 622 inside a cavity 625 for the embedding of a bridge die 522.

Referring first to FIG. 6A, a perforated glass panel 605 similar to that of FIG. 5A may be provided with trenches 607. Trenches 607 include open trenches 607′ to be filled with a conductive material to create through vias 632, and blind trenches 607″ to be filled with a conductive material to create bridge die vias 633. In FIG. 6A, a cavity 625 is shown as having been already provided in the glass panel 605, and the cavity may be provided in the same manner as described for the cavity 525 of FIGS. 5A-5D. In FIG. 6A, a protective film 613 may be provided on the top surface 627 of cavity 625. Protective or resist film 613 may include a dry resist material or a polyethylene terephthalate (PET) material, and is provided to protect the top surface 627 of cavity 625 from seed layer deposition, which will be described low in the context of FIG. 6B.

Referring now to FIG. 6B, a seed liner or seed layer 690 is provided to coat the walls of the trenches 607. The seed layer may for example be provided by way of atomic layer deposition (ALD), metal organic chemical vapor deposition (MOCVD) or physical vapor deposition (PVD), and may include titanium nitride along with a Ru or Cu seed. Here, resist film 613 is to protect the top surface 627 of cavity 625 from deposition of a seed layer thereon.

Referring now to FIG. 6C, the protective film 613 may be removed.

Referring to FIG. 6D, in the shown embodiment, a bridge die assembly 615 is provided within cavity 625. The bridge die assembly 615 includes a bridge die 622, and electrical coupling layer 641. Electrical coupling layer thus includes non-conductive component 645 defining holes therein, and electrically conductive structures 643, corresponding to contact pads 639 on bridge die 622, in the holes. In the embodiment of FIG. 6D, instead of providing the electrical coupling layer inside the cavity first, and thereafter providing the bridge die thereon, an assembly 615 may be provided which includes the combination of a bridge die and its electrical coupling layer, which assembly is then positioned in its corresponding cavity.

The electrical coupling layer 641 may be provided on the bridge die 622 in the same manners described above in relation to the provision of the electrical coupling layer 441 on the top surface 447 of cavity 425, in the same manners as noted above with respect to the first and second options described in the context of FIGS. 4A-4E, including the provision of an encapsulating/mold structure 435 in open spaces within the cavity, and, optionally, a polishing operation before the provision of buildup layers, and in the same manner as already described above in relation to FIG. 5D.

Referring now to FIG. 6E, the trenches may be filled with a conductive material using a bottom up fill approach, for example by plating (e.g. with Cu), chemical mechanical polishing (CMP) and/or resist patterning to create the through vias 632 and bridge die vias 633. After the provision of the vias 632 ad 633, with contact pads 632 of the bridge die 622 being in registration with the bridge die vias, operations similar to those noted in FIGS. 4D and 4E may be performed in order to arrive at a microelectronic structure comparable to the one shown in FIG. 4E, including the a polishing operation after provision of an encapsulating structure inside cavity spaces, and the provision of buildup layers on top and bottom surfaces of the substrate.

Referring first to FIG. 7A, a glass panel assembly 705 may be provided including a first glass panel 705′ and a second glass panel 705″ bonded together with a bond layer 751, which may include SiO2 and SiNx. The panels may be bonded together either at wafer level, or at package level. A cavity 725 is shown as having been provided in the panel 705′ and the cavity may be provided in the same manner as described for the cavity 525 of FIGS. 5A-5D.

Referring next to FIG. 7B, trenches 707 may be provided in the glass panel assembly 705. Trenches 707 include open trenches 707′ to be filled with a conductive material to create through vias 732, and blind trenches 707″ to be filled with a conductive material to create bridge die vias 733. The trenches 707″ stop at the bond layer 751 as shown.

Referring now to FIG. 7C, the vias 707 may be filled with a conductive material to provide through vias 732 and bridge die vias 733 as shown. For example, a seed liner may be provided to coat the walls of the trenches 707. The seed layer may for example be provided by way of atomic layer deposition (ALD), and may include titanium nitride along with a Ru or Cu seed. Here, bond layer 752 protects the top surface 727 of cavity 725 from deposition of a seed layer or conductive material thereon, similar to the role of film 613 of FIGS. 6A-6E.

Referring to FIG. 7D, in the shown embodiment, a bridge die assembly 715 is provided within cavity 725. The bridge die assembly 715 includes a bridge die 722, and electrical coupling layer 741. Electrical coupling layer thus includes non-conductive component 745 defining holes therein, and electrically conductive structures 743 in the holes. In the embodiment of FIG. 7D, similar to the embodiments of FIGS. 5A-5D and 6A-6E, an assembly 715 may be provided which includes the combination of a bridge die and its electrical coupling layer, which assembly is then positioned in its corresponding cavity.

The electrical coupling layer 741 may be provided on the bridge die 722 in the same manners described above in relation to the provision of the electrical coupling layer 441 on the top surface 447 of cavity 425, in the same manners as noted above with respect to the first and second options described in the context of FIGS. 4A-4E, including the provision of an encapsulating/mold structure 435 in open spaces within the cavity, and, optionally, a polishing operation before the provision of buildup layers, and in the same manner as already described above in relation to FIG. 5D.

After the provision of the bridge die assembly 715 inside the cavity 725, with contact pads 732 of the bridge die 722 being in registration with the bridge die vias, operations similar to those noted in FIGS. 4D and 4E may be performed in order to arrive at a microelectronic structure comparable to the one shown in FIG. 4E, including the a polishing operation after provision of an encapsulating structure inside cavity spaces, and the provision of buildup layers on top and bottom surfaces of the substrate.

Advantageously, a solution according to embodiments provides a practical solution for providing bridge dies with robust and reliable seals for its joints with the substrate into which the die is embedded. Embodiments example, make possible an electrical coupling between a substrate and the bridge die embedded therein where via pitches of about 100 μms are possible, using a die bonding film having for example a thickness of 50 μms. The die bonding film may adhere to a surface similar to a adherent tape, and may be peelable therefrom.

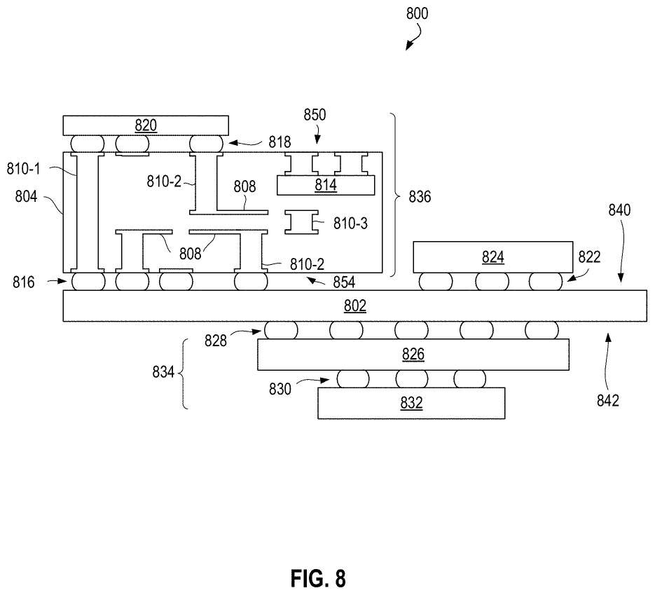

FIG. 8 is a cross-sectional side view of an integrated circuit device assembly 800 that may include one or more integrated circuit structures each including any of the microelectronic structure embodiments described herein (e. g. microelectronic structure 201 of FIG. 1, 301 of FIG. 3). The integrated circuit device assembly 800 includes a number of components disposed on a circuit board 802 (which may be a motherboard, system board, mainboard, etc.). The integrated circuit device assembly 800 includes components disposed on a first face 840 of the circuit board 802 and an opposing second face 842 of the circuit board 802; generally, components may be disposed on one or both faces 840 and 842. Any of the integrated circuit components discussed below with reference to the integrated circuit device assembly 800 may include an integrated circuit structure including a cascaded a MCP as disclosed herein.

In some embodiments, the circuit board 802 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 802. In other embodiments, the circuit board 802 may be a non-PCB substrate. The integrated circuit device assembly 800 illustrated in FIG. 8 includes a package-on-interposer structure 836 coupled to the first face 840 of the circuit board 802 by coupling components 816. The coupling components 816 may electrically and mechanically couple the package-on-interposer structure 836 to the circuit board 802, and may include solder balls (as shown in FIG. 8), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 836 may include an integrated circuit component 820 coupled to an interposer 804 by coupling components 818. The coupling components 818 may take any suitable form for the application, such as the forms discussed above with reference to the coupling components 816. Although a single integrated circuit component 820 is shown in FIG. 8, multiple integrated circuit components may be coupled to the interposer 804; indeed, additional interposers may be coupled to the interposer 804. The interposer 804 may provide an intervening substrate used to bridge the circuit board 802 and the integrated circuit component 820.

The integrated circuit component 820 may be a packaged or unpackaged integrated circuit product that includes one or more integrated circuit dies. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 820, a single monolithic integrated circuit die comprises solder bumps attached to contacts on the die. The solder bumps allow the die to be directly attached to the interposer 804. The integrated circuit component 820 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 820 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 820 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 820 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 804 may spread connections to a wider pitch or reroute a connection to a different connection. For example, the interposer 804 may couple the integrated circuit component 820 to a set of ball grid array (BGA) conductive contacts of the coupling components 816 for coupling to the circuit board 802. In the embodiment illustrated in FIG. 8, the integrated circuit component 820 and the circuit board 802 are attached to opposing sides of the interposer 804; in other embodiments, the integrated circuit component 820 and the circuit board 802 may be attached to a same side of the interposer 804. In some embodiments, three or more components may be interconnected by way of the interposer 804.

In some embodiments, the interposer 804 may be formed as a PCB, including multiple metal layers separated from one another by layers of dielectric material and interconnected by electrically conductive vias. In some embodiments, the interposer 804 may be formed of an epoxy resin, a fiberglass-reinforced epoxy resin, an epoxy resin with inorganic fillers, a ceramic material, or a polymer material such as polyimide. In some embodiments, the interposer 804 may be formed of alternate rigid or flexible materials that may include the same materials described above for use in a semiconductor substrate, such as silicon, germanium, and other group III-V and group IV materials. The interposer 804 may include metal interconnects 808 and vias 810, including but not limited to through hole vias 810-1 (that extend from a first face 850 of the interposer 804 to a second face 854 of the interposer 804), blind vias 810-2 (that extend from the first or second faces 850 or 854 of the interposer 804 to an internal metal layer), and buried vias 810-3 (that connect internal metal layers).

In some embodiments, the interposer 804 can comprise a silicon interposer. Through silicon vias (TSV) extending through the silicon interposer can connect connections on a first face of a silicon interposer to an opposing second face of the silicon interposer. In some embodiments, an interposer 804 comprising a silicon interposer can further comprise one or more routing layers to route connections on a first face of the interposer 804 to an opposing second face of the interposer 804.

The interposer 804 may further include embedded devices 814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 804. The package-on-interposer structure 836 may take the form of any of the package-on-interposer structures known in the art. In embodiments where the interposer is a non-printed circuit board

The integrated circuit device assembly 800 may include an integrated circuit component 824 coupled to the first face 840 of the circuit board 802 by coupling components 822. The coupling components 822 may take the form of any of the embodiments discussed above with reference to the coupling components 816, and the integrated circuit component 824 may take the form of any of the embodiments discussed above with reference to the integrated circuit component 820.

The integrated circuit device assembly 800 illustrated in FIG. 8 includes a package-on-package structure 834 coupled to the second face 842 of the circuit board 802 by coupling components 828. The package-on-package structure 834 may include an integrated circuit component 826 and an integrated circuit component 832 coupled together by coupling components 830 such that the integrated circuit component 826 is disposed between the circuit board 802 and the integrated circuit component 832. The coupling components 828 and 830 may take the form of any of the embodiments of the coupling components 816 discussed above, and the integrated circuit components 826 and 832 may take the form of any of the embodiments of the integrated circuit component 820 discussed above. The package-on-package structure 834 may be configured in accordance with any of the package-on-package structures known in the art.

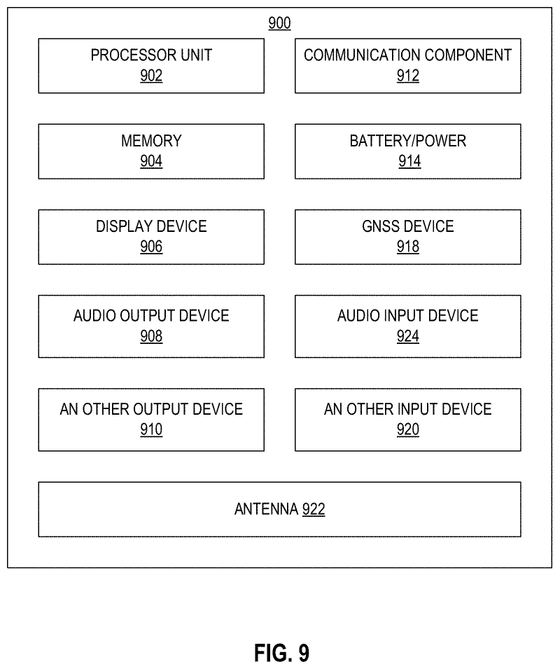

FIG. 9 is a block diagram of an example electrical device 900 that may include one or more of the embodiments of a microelectronic assembly disclosed herein. For example, any suitable ones of the components of the electrical device 900 may include one or more of the integrated circuit device assemblies 800, integrated circuit components 820, and/or embodiment MCPs disclosed herein. A number of components are illustrated in FIG. 9 as included in the electrical device 900, but any one or more of these components may be omitted or duplicated, as suitable for the application. In some embodiments, some or all of the components included in the electrical device 900 may be attached to one or more motherboards mainboards, or system boards. In some embodiments, one or more of these components are fabricated onto a single system-on-a-chip (SoC) die.

Additionally, in various embodiments, the electrical device 900 may not include one or more of the components illustrated in FIG. 9, but the electrical device 900 may include interface circuitry for coupling to the one or more components. For example, the electrical device 900 may not include a display device 906, but may include display device interface circuitry (e.g., a connector and driver circuitry) to which a display device 906 may be coupled. In another set of examples, the electrical device 900 may not include an audio input device 924 or an audio output device 908, but may include audio input or output device interface circuitry (e.g., connectors and supporting circuitry) to which an audio input device 924 or audio output device 908 may be coupled.

The electrical device 900 may include one or more processor units 902 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 902 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 900 may include a memory 904, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 904 may include memory that is located on the same integrated circuit die as the processor unit 902. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 900 can comprise one or more processor units 902 that are heterogeneous or asymmetric to another processor unit 902 in the electrical device 900. There can be a variety of differences between the processing units 902 in a system in terms of a spectrum of metrics of merit including architectural, microarchitectural, thermal, power consumption characteristics, and the like. These differences can effectively manifest themselves as asymmetry and heterogeneity among the processor units 902 in the electrical device 900.

In some embodiments, the electrical device 900 may include a communication component 912 (e.g., one or more communication components). For example, the communication component 912 can manage wireless communications for the transfer of data to and from the electrical device 900. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-1005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 912 may operate in accordance with other wireless protocols in other embodiments. The electrical device 900 may include one or more antennas, such as antenna 922 to facilitate wireless communications and/or to receive other wireless communications (such as AM or FM radio transmissions).

In some embodiments, the communication component 912 may manage wired communications, such as electrical, optical, or any other suitable communication protocols (e.g., IEEE 802.3 Ethernet standards). As noted above, the communication component 912 may include multiple communication components. For instance, a first communication component 912 may be dedicated to shorter-range wireless communications such as Wi-Fi or Bluetooth, and a second communication component 912 may be dedicated to longer-range wireless communications such as global positioning system (GPS), EDGE, GPRS, CDMA, WiMAX, LTE, EV-DO, or others. In some embodiments, a first communication component 912 may be dedicated to wireless communications, and a second communication component 912 may be dedicated to wired communications.

The electrical device 900 may include battery/power circuitry 914. The battery/power circuitry 914 may include one or more energy storage devices (e.g., batteries or capacitors) and/or circuitry for coupling components of the electrical device 900 to an energy source separate from the electrical device 900 (e.g., AC line power).

The electrical device 900 may include a display device 906 (or corresponding interface circuitry, as discussed above). The display device 906 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 900 may include an audio output device 908 (or corresponding interface circuitry, as discussed above). The audio output device 908 may include any embedded or wired or wirelessly connected external device that generates an audible indicator, such speakers, headsets, or earbuds.

The electrical device 900 may include an audio input device 924 (or corresponding interface circuitry, as discussed above). The audio input device 924 may include any embedded or wired or wirelessly connected device that generates a signal representative of a sound, such as microphones, microphone arrays, or digital instruments (e.g., instruments having a musical instrument digital interface (MIDI) output). The electrical device 900 may include a Global Navigation Satellite System (GNSS) device 918 (or corresponding interface circuitry, as discussed above), such as a Global Positioning System (GPS) device. The GNSS device 918 may be in communication with a satellite-based system and may determine a geolocation of the electrical device 900 based on information received from one or more GNSS satellites, as known in the art.

The electrical device 900 may include another output device 910 (or corresponding interface circuitry, as discussed above). Examples of the other output device 910 may include an audio codec, a video codec, a printer, a wired or wireless transmitter for providing information to other devices, or an additional storage device.

The electrical device 900 may include another input device 920 (or corresponding interface circuitry, as discussed above). Examples of the other input device 920 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 900 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 900 may be any other electronic device that processes data. In some embodiments, the electrical device 900 may comprise multiple discrete physical components. Given the range of devices that the electrical device 900 can be manifested as in various embodiments, in some embodiments, the electrical device 900 can be referred to as a computing device or a computing system.

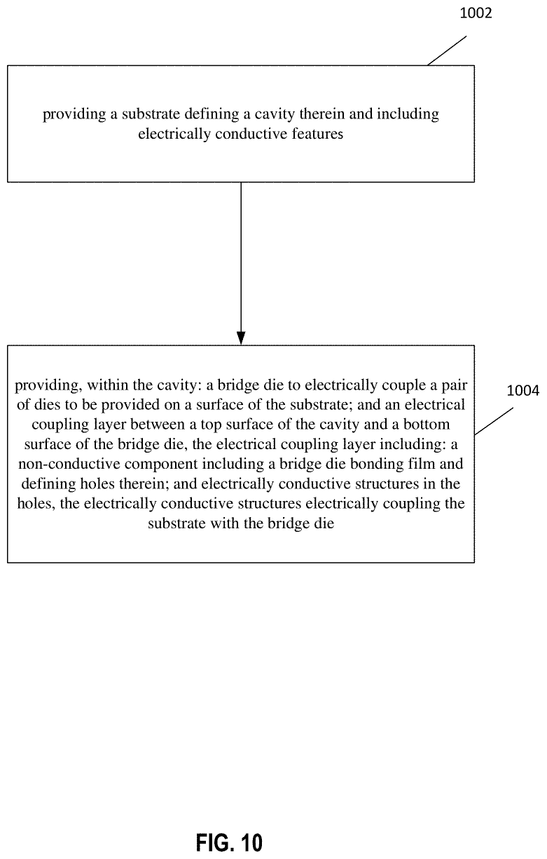

FIG. 10 is a flow chart of a process 1000 of making a microelectronic structure of a semiconductor package according to some embodiments. At operation 1002, the process includes providing a substrate defining a cavity therein and including electrically conductive features. At process 1004, the process includes providing, within the cavity: a bridge die to electrically couple a pair of dies to be provided on a surface of the substrate; and an electrical coupling layer between a top surface of the cavity and a bottom surface of the bridge die, the electrical coupling layer including: a non-conductive component including a die bonding film and defining holes therein; and electrically conductive structures in the holes, the electrically conductive structures electrically coupling the substrate with the bridge die.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of embodiments has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

In embodiments, the phrase “A is located on B” means that at least a part of A is in direct physical contact or indirect physical contact (having one or more other features between A and B) with at least a part of B.

In the instant description, “A is adjacent to B” means that at least part of A is in direct physical contact with at least a part of B.

In the instant description, “B is between A and C” means that at least part of B is in or along a space separating A and C and that the at least part of B is in direct or indirect physical contact with A and C.

In the instant description, “A is attached to B” means that at least part of A is mechanically attached to at least part of B, either directly or indirectly (having one or more other features between A and B).

The use of reference numerals separated by a “/”, such as “102/104” for example, is intended to refer to 102 or 104 as appropriate. Otherwise, the forward slash (“/”) as used herein means “and/or.”

The use of the techniques and structures provided herein can be detected using tools such as: electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. In particular, such tools can indicate an integrated circuit including at least one MCP including an interposer bonded to a MCP subassembly through direct dielectric-to-dielectric bonding as described herein.

In some embodiments, the techniques, processes and/or methods described herein can be detected based on the structures formed therefrom. In addition, in some embodiments, the techniques and structures described herein can be detected based on the benefits derived therefrom. Numerous configurations and variations will be apparent in light of this disclosure.

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” “according to some embodiments,” “in accordance with embodiments,” or “in embodiments,” which may each refer to one or more of the same or different embodiments. Furthermore, the terms “comprising,” “including,” “having,” and the like, as used with respect to embodiments of the present disclosure, are synonymous.

“Coupled” as used herein means that two or more elements are in direct physical contact, or that that two or more elements indirectly physically contact each other, but yet still cooperate or interact with each other (i.e. one or more other elements are coupled or connected between the elements that are said to be coupled with each other). The term “directly coupled” means that two or more elements are in direct contact.

As used herein, the term “module” refers to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

As used herein, an “integrated circuit structure” may include one or more microelectronic dies.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc., as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the elements that are connected, without any intermediary devices. The term “coupled” means a direct or indirect connection, such as a direct electrical, mechanical, or magnetic connection between the elements that are connected or an indirect connection, through one or more passive or active intermediary devices. The term “signal” may refer to at least one current signal, voltage signal, magnetic signal, or data/clock signal. The meaning of “a,” “an,” and “the” include plural references. The meaning of “in” includes “in” and “on.”

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For purposes of the embodiments, the transistors in various circuits and logic blocks described here are metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BiCMOS, CMOS, eFET, etc., may be used without departing from the scope of the disclosure. The term “MN” indicates an n-type transistor (e.g., nMOS, NPN BJT, etc.) and the term “MP” indicates a p-type transistor (e.g., pMOS, PNP BJT, etc.).

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

### Examples

Some non-limiting example embodiments are set forth below.

Example 1 includes a microelectronic structures including: a substrate defining a cavity therein; a bridge die within the cavity, the bridge die to electrically couple a pair of dies to be provided on a surface of the substrate; an electrical coupling layer between a top surface of the cavity and a bottom surface of the bridge die, the electrical coupling layer including: a non-conductive component including a die bonding film and defining holes therein; and electrically conductive structures in the holes, the electrically conductive structures electrically coupling the substrate with the bridge die.

Example 2 includes the subject matter of Example 1, further including electrical contact pads at the bottom surface of the bridge die, the contact pads in the holes of the non-conductive component, and in registration with corresponding ones of the electrically conductive structures.

Example 3 includes the subject matter of Example 1, wherein the electrically conductive structures include liquid metal.

Example 4 includes the subject matter of Example 3, wherein the liquid metal includes gallium, or an alloy of gallium.

Example 5 includes the subject matter of Example 4, wherein the alloy of gallium includes at least one of an alloy of gallium and indium, a eutectic alloy of gallium, indium, and tin, or a eutectic alloy of gallium, indium, and zinc.

Example 6 includes the subject matter of Example 3, wherein the substrate includes first electrically conductive features therein, and the die includes second electrically conductive features therein, the microelectronic structure further including caps comprising nickel or tungsten between the electrically conductive structures on one hand, and at least one of respective ones of the first electrically conductive features or the second electrically conductive features that are adjacent the electrically conductive structures.

Example 7 includes the subject matter of Example 1, wherein the electrically conductive structures include contact pads at the bottom surface of the bridge die.

Example 8 includes the subject matter of Example 1, wherein the electrically conductive structures include solder.

Example 9 includes the subject matter of Example 1, wherein the non-conductive component includes a polymer.

Example 10 includes the subject matter of Example 9, wherein the non-conductive component includes at least one of: epoxy, polyimide, bismaleimide, acrylate, silicone, cyanate ester, silica, alumina, aluminum hydroxide, mica, glass, polyethylene terephthalate polyolefin, copolymer polypropylene, block copolymer polypropylene, homopolypropylene, polybutene, polymethylpentene, ethylene-vinylacetate copolymer, ionomer resin, ethylene(meth)acrylic acid copolymer, ethylene(meth)acrylic acid ester (random or alternating) copolymer, ethylene-butene copolymer, ethylene-hexene copolymer, polyurethane, polyester, polyethyleneterephthalate, polyethylenenaphthalate, polycarbonate, polyetheretherketone, polyimide, polyetherimide, polyamide, whole aromatic polyamide, polyphenylsulfide, fluorine resin, polyvinyl chloride, polyvinylidene chloride, a cellulose resin, or a silicone resin.

Example 11 includes the subject matter of Example 1, further including an adhesive on the non-conductive component to bond the non-conductive component to the bridge die at one surface thereof and to the top surface of the cavity at another surface thereof.

Example 12 includes the subject matter of Example 1, wherein the bridge die includes electrically conductive features therein including through vias.

Example 13 includes the subject matter of Example 1, wherein the substrate includes electrically conductive features therein including through vias and bridge vias, wherein the electrically conductive structures are in registration with the bridge vias to electrically couple the substrate with the bridge die.

Example 14 includes the subject matter of Example 1, wherein the substrate includes glass, silicon or an organic material.

Example 15 includes the subject matter of Example 1, wherein the substrate includes two glass panels bonded together with a SiO2 layer.

Example 16 includes a semiconductor package including: a microelectronic subassembly including: a substrate defining a cavity therein; a bridge die within the cavity; an electrical coupling layer between a top surface of the cavity and a bottom surface of the bridge die, the electrical coupling layer including: a non-conductive component including a die bonding film and defining holes therein; and electrically conductive structures in the holes, the electrically conductive structures electrically coupling the substrate with the bridge die; and a pair of surface dies on a surface of the microelectronic subassembly and electrically coupled to the bridge die such that the bridge die provides an electrical coupling between the pair of surface dies.

Example 17 includes the subject matter of Example 16, further including electrical contact pads at the bottom surface of the bridge die, the contact pads in the holes of the non-conductive component, and in registration with corresponding ones of the electrically conductive structures.

Example 18 includes the subject matter of Example 16, wherein the electrically conductive structures include liquid metal.

Example 19 includes the subject matter of Example 18, wherein the liquid metal includes gallium, or an alloy of gallium.

Example 20 includes the subject matter of Example 19, wherein the alloy of gallium includes at least one of an alloy of gallium and indium, a eutectic alloy of gallium, indium, and tin, or a eutectic alloy of gallium, indium, and zinc.

Example 21 includes the subject matter of Example 18, wherein the substrate includes first electrically conductive features therein, and the die includes second electrically conductive features therein, the semiconductor package further including caps comprising nickel or tungsten between the electrically conductive structures on one hand, and at least one of respective ones of the first electrically conductive features or the second electrically conductive features that are adjacent the electrically conductive structures.

Example 22 includes the subject matter of Example 16, wherein the electrically conductive structures include contact pads at the bottom surface of the bridge die.

Example 23 includes the subject matter of Example 16, wherein the electrically conductive structures include solder.

Example 24 includes the subject matter of Example 16, wherein the non-conductive component includes a polymer.

Example 25 includes the subject matter of Example 24, wherein the non-conductive component includes at least one of: epoxy, polyimide, bismaleimide, acrylate, silicone, cyanate ester, silica, alumina, aluminum hydroxide, mica, glass, polyethylene terephthalate polyolefin, copolymer polypropylene, block copolymer polypropylene, homopolypropylene, polybutene, polymethylpentene, ethylene-vinylacetate copolymer, ionomer resin, ethylene(meth)acrylic acid copolymer, ethylene(meth)acrylic acid ester (random or alternating) copolymer, ethylene-butene copolymer, ethylene-hexene copolymer, polyurethane, polyester, polyethyleneterephthalate, polyethylenenaphthalate, polycarbonate, polyetheretherketone, polyimide, polyetherimide, polyamide, whole aromatic polyamide, polyphenylsulfide, fluorine resin, polyvinyl chloride, polyvinylidene chloride, a cellulose resin, or a silicone resin.

Example 26 includes the subject matter of Example 16, further including an adhesive on the non-conductive component to bond the non-conductive component to the bridge die at one surface thereof and to the top surface of the cavity at another surface thereof.

Example 27 includes the subject matter of Example 16, wherein the bridge die includes electrically conductive features therein including through vias.

Example 28 includes the subject matter of Example 16, wherein the substrate includes electrically conductive features therein including through vias and bridge vias, wherein the electrically conductive structures are in registration with the bridge vias to electrically couple the substrate with the bridge die.

Example 29 includes the subject matter of Example 16, wherein the substrate includes glass, silicon or an organic material.

Example 30 includes the subject matter of Example 16, wherein the substrate includes two glass panels bonded together with a SiO2 layer.

Example 31 includes an integrated circuit (IC) device assembly including: a printed circuit board; and a plurality of integrated circuit components coupled to the printed circuit board, individual ones of the integrated circuit components including one or more semiconductor packages, individual ones of the semiconductor packages including a microelectronic assembly including: a microelectronic subassembly including: a substrate defining a cavity therein; a bridge die within the cavity; an electrical coupling layer between a top surface of the cavity and a bottom surface of the bridge die, the electrical coupling layer including: a non-conductive component including a die bonding film and defining holes therein; and electrically conductive structures in the holes, the electrically conductive structures electrically coupling the substrate with the bridge die; and a pair of surface dies on a surface of the microelectronic subassembly and electrically coupled to the bridge die such that the bridge die provides an electrical coupling between the pair of surface dies.

Example 32 includes the subject matter of Example 31, further including electrical contact pads at the bottom surface of the bridge die, the contact pads in the holes of the non-conductive component, and in registration with corresponding ones of the electrically conductive structures.

Example 33 includes the subject matter of Example 31, wherein the electrically conductive structures include liquid metal.

Example 34 includes the subject matter of Example 33, wherein the liquid metal includes gallium, or an alloy of gallium.

Example 35 includes the subject matter of Example 34, wherein the alloy of gallium includes at least one of an alloy of gallium and indium, a eutectic alloy of gallium, indium, and tin, or a eutectic alloy of gallium, indium, and zinc.

Example 36 includes the subject matter of Example 33, wherein the substrate includes first electrically conductive features therein, and the die includes second electrically conductive features therein, the microelectronic assembly further including caps comprising nickel or tungsten between the electrically conductive structures on one hand, and at least one of respective ones of the first electrically conductive features or the second electrically conductive features that are adjacent the electrically conductive structures.

Example 37 includes the subject matter of Example 31, wherein the electrically conductive structures include contact pads at the bottom surface of the bridge die.

Example 38 includes the subject matter of Example 31, wherein the electrically conductive structures include solder.

Example 39 includes the subject matter of Example 31, wherein the non-conductive component includes a polymer.

Example 40 includes the subject matter of Example 39, wherein the non-conductive component includes at least one of: epoxy, polyimide, bismaleimide, acrylate, silicone, cyanate ester, silica, alumina, aluminum hydroxide, mica, glass, polyethylene terephthalate polyolefin, copolymer polypropylene, block copolymer polypropylene, homopolypropylene, polybutene, polymethylpentene, ethylene-vinylacetate copolymer, ionomer resin, ethylene(meth)acrylic acid copolymer, ethylene(meth)acrylic acid ester (random or alternating) copolymer, ethylene-butene copolymer, ethylene-hexene copolymer, polyurethane, polyester, polyethyleneterephthalate, polyethylenenaphthalate, polycarbonate, polyetheretherketone, polyimide, polyetherimide, polyamide, whole aromatic polyamide, polyphenylsulfide, fluorine resin, polyvinyl chloride, polyvinylidene chloride, a cellulose resin, or a silicone resin.

Example 41 includes the subject matter of Example 31, further including an adhesive on the non-conductive component to bond the non-conductive component to the bridge die at one surface thereof and to the top surface of the cavity at another surface thereof.

Example 42 includes the subject matter of Example 31, wherein the bridge die includes electrically conductive features therein including through vias.

Example 43 includes the subject matter of Example 31, wherein the substrate includes electrically conductive features therein including through vias and bridge vias, wherein the electrically conductive structures are in registration with the bridge vias to electrically couple the substrate with the bridge die.

Example 44 includes the subject matter of Example 31, wherein the substrate includes glass, silicon or an organic material.

Example 45 includes the subject matter of Example 31, wherein the substrate includes two glass panels bonded together with a SiO2 layer.

Example 46 includes a method to form a microelectronic structure of a semiconductor package, the method including: providing a substrate defining a cavity therein and including electrically conductive features; providing, within the cavity: a bridge die to electrically couple a pair of dies to be provided on a surface of the substrate; and an electrical coupling layer between a top surface of the cavity and a bottom surface of the bridge die, the electrical coupling layer including: a non-conductive component including a die bonding film and defining holes therein; and electrically conductive structures in the holes, the electrically conductive structures electrically coupling the substrate with the bridge die.

Example 47 includes the subject matter of Example 46, wherein providing the substrate includes: providing a substrate panel; providing via trenches extending through the substrate, the via trenches including open trenches and bridge trenches; filling the via trenches with an electrically conductive material to form through vias in the open trenches, and bridge vias in the bridge trenches; and providing the cavity in the substrate panel prior to or after filling the via trenches, wherein the bridge vias extend up the top surface of the cavity.

Example 48 includes the subject matter of Example 47, wherein providing the electrical coupling layer includes one of, prior to providing the bridge die within the cavity: placing the electrical coupling layer on the top surface of the cavity; or forming the electrical coupling layer on a top surface of the cavity by placing a die bonding film material on the top surface of the cavity, forming the holes therein, and providing the electrically conductive structures within the holes.

Example 49 includes the subject matter of Example 48, wherein forming the holes includes using a semi-additive process.

Example 50 includes the subject matter of Example 48, wherein filling the via trenches including filling the via trenches using a bottom up fill process after providing the bridge die within the cavity.

Example 51 includes the subject matter of Example 48, wherein providing the bridge die in the cavity includes placing the bridge die on a top surface of the electrical coupling layer after the electrical coupling layer has been provided within the cavity.

Example 52 includes the subject matter of Example 46, wherein providing the electrical coupling layer within the cavity includes providing the electrical coupling layer on the bottom surface of the bridge die to form a bridge die assembly therewith, and placing the bridge die assembly on a top surface of the cavity.

Example 53 includes the subject matter of Example 52, wherein providing the electrical coupling layer on the bottom surface of the bridge die includes one of, prior to placing the bridge die assembly within the cavity: placing the electrical coupling layer on the bottom surface of the bridge die; or forming the electrical coupling layer on the bottom surface of the bridge die by placing a die bonding film material on the bottom surface of the bridge die, forming the holes therein, and providing the electrically conductive structures within the holes.

Example 54 includes the subject matter of Example 52, wherein providing the bridge die within the cavity includes placing the bridge die within the cavity such that one of its front-end or its backend faces the to surface of the cavity.

Example 55 includes the subject matter of Example 46, further including electrical contact pads at the bottom surface of the bridge die, the contact pads in the holes of the non-conductive component, and in registration with corresponding ones of the electrically conductive structures.

Example 56 includes the subject matter of Example 46, wherein the electrically conductive structures include liquid metal.

Example 57 includes the subject matter of Example 56, wherein the liquid metal includes gallium, or an alloy of gallium.

Example 58 includes the subject matter of Example 57, wherein the alloy of gallium includes at least one of an alloy of gallium and indium, a eutectic alloy of gallium, indium, and tin, or a eutectic alloy of gallium, indium, and zinc.

Example 59 includes the subject matter of Example 56, wherein the substrate includes first electrically conductive features therein, and the die includes second electrically conductive features therein, the method including providing caps comprising nickel or tungsten between the electrically conductive structures on one hand, and at least one of respective ones of the first electrically conductive features or the second electrically conductive features that are adjacent the electrically conductive structures.

Example 60 includes the subject matter of Example 46, wherein the electrically conductive structures include contact pads at the bottom surface of the bridge die.

Example 61 includes the subject matter of Example 46, wherein the electrically conductive structures include solder.

Example 62 includes the subject matter of Example 46, wherein the non-conductive component includes a polymer.

Example 63 includes the subject matter of Example 62, wherein the non-conductive component includes at least one of: epoxy, polyimide, bismaleimide, acrylate, silicone, cyanate ester, silica, alumina, aluminum hydroxide, mica, glass, polyethylene terephthalate polyolefin, copolymer polypropylene, block copolymer polypropylene, homopolypropylene, polybutene, polymethylpentene, ethylene-vinylacetate copolymer, ionomer resin, ethylene(meth)acrylic acid copolymer, ethylene(meth)acrylic acid ester (random or alternating) copolymer, ethylene-butene copolymer, ethylene-hexene copolymer, polyurethane, polyester, polyethyleneterephthalate, polyethylenenaphthalate, polycarbonate, polyetheretherketone, polyimide, polyetherimide, polyamide, whole aromatic polyamide, polyphenylsulfide, fluorine resin, polyvinyl chloride, polyvinylidene chloride, a cellulose resin, or a silicone resin.

Example 64 includes the subject matter of Example 46, further including providing an adhesive on the non-conductive component to bond the non-conductive component to the bridge die at one surface thereof and to the top surface of the cavity at another surface thereof.

Example 65 includes the subject matter of Example 46, wherein the bridge die includes electrically conductive features therein including through vias.

Example 66 includes the subject matter of Example 46, wherein the substrate includes electrically conductive features therein including through vias and bridge vias, wherein the electrically conductive structures are in registration with the bridge vias to electrically couple the substrate with the bridge die.

Example 67 includes the subject matter of Example 46, wherein the substrate includes glass, silicon or an organic material.

Example 68 includes the subject matter of Example 46, wherein the substrate includes two glass panels bonded together with a SiO2 layer.

What is claimed is:

1. A microelectronic structure, comprising:
a substrate defining a cavity therein;
a bridge die within the cavity, the bridge die to electrically couple a pair of dies to be provided on a surface of the substrate;
an electrical coupling layer between a top surface of the cavity and a bottom surface of the bridge die, the electrical coupling layer including:
a non-conductive component including a die bonding film and defining holes therein; and
electrically conductive structures in the holes, the electrically conductive structures electrically coupling the substrate with the bridge die.

2. The microelectronic structure of claim 1, further including electrical contact pads at the bottom surface of the bridge die, the contact pads in the holes of the non-conductive component, and in registration with corresponding ones of the electrically conductive structures.

3. The microelectronic structure of claim 1, wherein the electrically conductive structures include liquid metal.

4. The microelectronic structure of claim 3, wherein the liquid metal includes gallium, or an alloy of gallium.

5. The microelectronic structure of claim 4, wherein the alloy of gallium includes at least one of an alloy of gallium and indium, a eutectic alloy of gallium, indium, and tin, or a eutectic alloy of gallium, indium, and zinc.

6. The microelectronic structure of claim 3, wherein the substrate includes first electrically conductive features therein, and the die includes second electrically conductive features therein, the microelectronic structure further including caps comprising nickel or tungsten between the electrically conductive structures on one hand, and at least one of respective ones of the first electrically conductive features or the second electrically conductive features that are adjacent the electrically conductive structures.

7. The microelectronic structure of claim 1, wherein the electrically conductive structures include contact pads at the bottom surface of the bridge die.

8. The microelectronic structure of claim 1, wherein the electrically conductive structures include solder.

9. The microelectronic structure of claim 1, wherein the non-conductive component includes a polymer.

10. The microelectronic structure of claim 9, wherein the non-conductive component includes at least one of: epoxy, polyimide, bismaleimide, acrylate, silicone, cyanate ester, silica, alumina, aluminum hydroxide, mica, glass, polyethylene terephthalate polyolefin, copolymer polypropylene, block copolymer polypropylene, homopolypropylene, polybutene, polymethylpentene, ethylene-vinylacetate copolymer, ionomer resin, ethylene(meth)acrylic acid copolymer, ethylene(meth)acrylic acid ester (random or alternating) copolymer, ethylene-butene copolymer, ethylene-hexene copolymer, polyurethane, polyester, polyethyleneterephthalate, polyethylenenaphthalate, polycarbonate, polyetheretherketone, polyimide, polyetherimide, polyamide, whole aromatic polyamide, polyphenylsulfide, fluorine resin, polyvinyl chloride, polyvinylidene chloride, a cellulose resin, or a silicone resin.

11. The microelectronic structure of claim 1, further including an adhesive on the non-conductive component to bond the non-conductive component to the bridge die at one surface thereof and to the top surface of the cavity at another surface thereof.

12. The microelectronic structure of claim 1, wherein the substrate includes electrically conductive features therein including through vias and bridge vias, wherein the electrically conductive structures are in registration with the bridge vias to electrically couple the substrate with the bridge die.

13. The microelectronic structure of claim 1, wherein the substrate includes glass, silicon or an organic material.

14. A semiconductor package, comprising:
a microelectronic subassembly including:
a substrate defining a cavity therein;
a bridge die within the cavity;
an electrical coupling layer between a top surface of the cavity and a bottom surface of the bridge die, the electrical coupling layer including:
a non-conductive component including a die bonding film and defining holes therein; and
electrically conductive structures in the holes, the electrically conductive structures electrically coupling the substrate with the bridge die; and
a pair of surface dies on a surface of the microelectronic subassembly and electrically coupled to the bridge die such that the bridge die provides an electrical coupling between the pair of surface dies.

15. The semiconductor package of claim 14, further including electrical contact pads at the bottom surface of the bridge die, the contact pads in the holes of the non-conductive component, and in registration with corresponding ones of the electrically conductive structures.

16. The semiconductor package of claim 14, wherein the electrically conductive structures include liquid metal.

17. The semiconductor package of claim 16, wherein the liquid metal includes gallium, or an alloy of gallium.

18. An integrated circuit (IC) device assembly including:
a printed circuit board; and
a plurality of integrated circuit components coupled to the printed circuit board, individual ones of the integrated circuit components including one or more semiconductor packages, individual ones of the semiconductor packages including a microelectronic assembly including:
a microelectronic subassembly including:
a substrate defining a cavity therein;
a bridge die within the cavity;
an electrical coupling layer between a top surface of the cavity and a bottom surface of the bridge die, the electrical coupling layer including:
a non-conductive component including a die bonding film and defining holes therein; and
electrically conductive structures in the holes, the electrically conductive structures electrically coupling the substrate with the bridge die; and
a pair of surface dies on a surface of the microelectronic subassembly and electrically coupled to the bridge die such that the bridge die provides an electrical coupling between the pair of surface dies.

19. The IC device assembly of claim 18, wherein the electrically conductive structures include liquid metal, the liquid metal including gallium, or an alloy of gallium.

20. The microelectronic assembly of claim 18, wherein the non-conductive component includes at least one of: epoxy, polyimide, bismaleimide, acrylate, silicone, cyanate ester, silica, alumina, aluminum hydroxide, mica, glass, polyethylene terephthalate polyolefin, copolymer polypropylene, block copolymer polypropylene, homopolypropylene, polybutene, polymethylpentene, ethylene-vinylacetate copolymer, ionomer resin, ethylene(meth)acrylic acid copolymer, ethylene(meth)acrylic acid ester (random or alternating) copolymer, ethylene-butene copolymer, ethylene-hexene copolymer, polyurethane, polyester, polyethyleneterephthalate, polyethylenenaphthalate, polycarbonate, polyetheretherketone, polyimide, polyetherimide, polyamide, whole aromatic polyamide, polyphenylsulfide, fluorine resin, polyvinyl chloride, polyvinylidene chloride, a cellulose resin, or a silicone resin.

21. A method to form a microelectronic structure of a semiconductor package, the method including:
providing a substrate defining a cavity therein and including electrically conductive features;
providing, within the cavity:
a bridge die to electrically couple a pair of dies to be provided on a surface of the substrate; and
an electrical coupling layer between a top surface of the cavity and a bottom surface of the bridge die, the electrical coupling layer including:
a non-conductive component including a die bonding film and defining holes therein; and
electrically conductive structures in the holes, the electrically conductive structures electrically coupling the substrate with the bridge die.

22. The method of claim 21, wherein providing the substrate includes:
providing a substrate panel;
providing via trenches extending through the substrate, the via trenches including open trenches and bridge trenches;
filling the via trenches with an electrically conductive material to form through vias in the open trenches, and bridge vias in the bridge trenches; and
providing the cavity in the substrate panel prior to or after filling the via trenches, wherein the bridge vias extend up the top surface of the cavity.

23. The method of claim 22, wherein providing the electrical coupling layer includes one of, prior to providing the bridge die within the cavity:
placing the electrical coupling layer on the top surface of the cavity; or
forming the electrical coupling layer on a top surface of the cavity by placing a die bonding film material on the top surface of the cavity, forming the holes therein, and providing the electrically conductive structures within the holes.

24. The method of claim 23, wherein providing the bridge die in the cavity includes placing the bridge die on a top surface of the electrical coupling layer after the electrical coupling layer has been provided within the cavity.

25. The method of claim 21, wherein providing the electrical coupling layer within the cavity includes providing the electrical coupling layer on the bottom surface of the bridge die to form a bridge die assembly therewith, and placing the bridge die assembly on a top surface of the cavity.
